(19) United States
(12) Patent Application Publication
(10) Pub. No.: US 2009/0230389 A1
(43) Pub. Date: Sep. 17, 2009

(54) Atomic Layer Deposition of Gate Dielectric Layer with High Dielectric Constant for Thin Film Transisitor

(76) Inventors: Zhizhang Chen, Corvallis, OR (US); Thomas H. Dukes, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/251,085

(22) Filed: Oct. 14, 2008

Related U.S. Application Data
(60) Provisional application No. 61/037,099, filed on Mar. 17, 2008.

(51) Int. Cl. H01L 29/786; H01L 21/34

(52) U.S. Cl. 257/43; 438/104; 257/E29.296; 257/E21.459

(57) ABSTRACT

Embodiments of a thin film transistor with an atomic layer deposition gate dielectric layer having a high dielectric constant and a zinc indium oxide channel are disclosed.

### CROSS-REFERENCE TO RELATED APPLICATIONS

This Application claims the benefit of U.S. Provisional patent application Ser. No. 61/037,099, filed Mar. 17, 2008, which is hereby incorporated by reference in it's entirety.

### BACKGROUND

In order to form thin film transistors on flexible or other low temperature substrates (e.g., plastic), the temperatures of the manufacturing process are kept sufficiently low to prevent the substrate from melting or otherwise deforming. Unfortunately, the use of low temperatures processes in forming thin film transistors may produce transistors with less than optimal electrical characteristics. These characteristics can include low drive current due to low electron mobility, high leakage current, unstable turn on voltage, and large hysterisis due to charge/trap states in the gate oxide, the semiconductor channel, and the oxide-channel interface.

### BRIEF DESCRIPTION OF THE DRAWINGS

FIG. 1 is a cross sectional view illustrating an embodiment of a low temperature thin film transistor.

FIG. 2 is a flow chart illustrating an embodiment of a method for forming a low temperature thin film transistor.

FIGS. 3A-3D are cross sectional views illustrating an embodiment of forming a low temperature thin film transistor.

FIG. 4 is schematic diagram illustrating an embodiment of a display array that includes the low temperature thin film transistor of FIG. 1.

### DETAILED DESCRIPTION

In the following detailed description, reference is made to the accompanying drawings, which form a part hereof, and in which is shown by way of illustration specific embodiments in which the disclosed subject matter may be practiced. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

According to one embodiment, a low temperature thin film transistor (TFT) is provided. The transistor includes a gate dielectric layer that is formed with a high dielectric constant (K) material using a low temperature (e.g., less than 200° C.) atomic layer deposition (ALD) process. A thin film metal oxide semiconductor (e.g., ZIO), sputtered at room temperature, forms a channel layer that interfaces with the high K gate dielectric layer. The combination of the low temperature ALD technique for high K gate dielectric with low temperature metal oxide semiconductor thin film produces a low defect gate dielectric layer and high quality interface between the gate oxide and the semiconductor channel. The combination significantly improves TFT device performance and stability compared to TFTs with ALD or sputtered aluminum oxide as the gate dielectric and traditional a-Si TFT devices. The TFT may be formed on a low temperature substrate (e.g., a plastic substrate) using conventional semiconductor techniques.

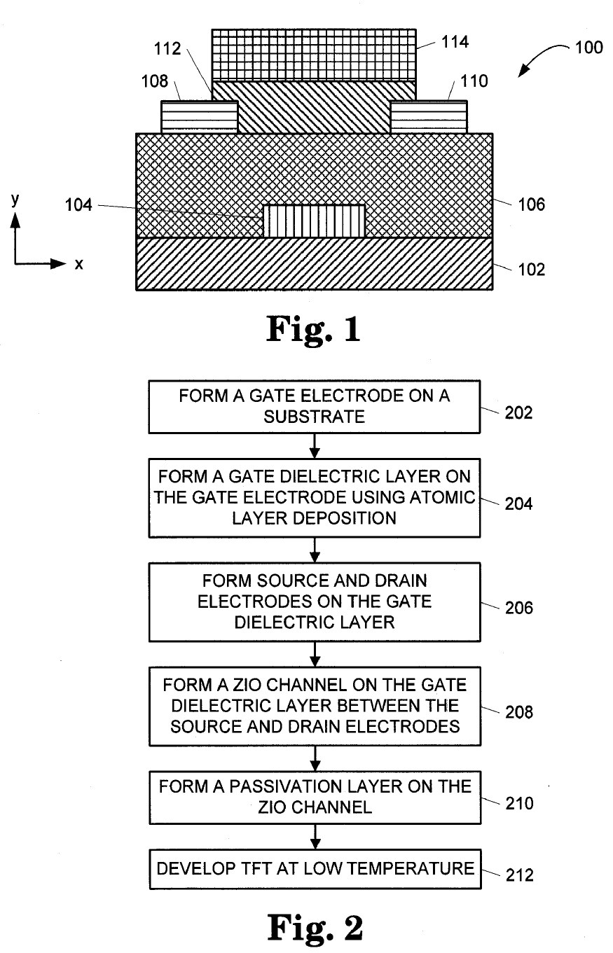

FIG. 1 is a cross sectional view illustrating an embodiment of a low temperature thin film transistor (TFT) 100 formed on a substrate 102. TFT 100 includes a gate electrode 104, a gate dielectric layer 106 with a high dielectric constant (κ), a source electrode 108, a drain electrode 110, a semiconductor channel 112, and a passivation layer 114.

TFT 100 is a solid-state device configured to conduct electrical current through channel 112 between source electrode 108 and drain electrode 110 in accordance with a voltage applied to gate electrode 104. For example, current may flow from source electrode 108 to drain electrode 110 in response to a voltage above a threshold voltage being applied to gate electrode 104 and a voltage difference being applied between source electrode 108 and drain electrode 110 in one embodiment.

TFT 100 is constructed in thin layers at relatively low temperatures (e.g., less than 200° C.) using transparent and colorless materials in one embodiment. In particular, gate dielectric layer 106 is formed as a thin film with a high dielectric constant material (e.g., HfO₂ or ZrO₂) using an atomic layer deposition (ALD) process. The use of the ALD process and a high dielectric constant material in gate dielectric layer 106 allow TFT 100 to be constructed using a low temperature annealing process (e.g., an anneal of 175° C. for 1 hr in air) while providing desirable electrical characteristics. For example, gate dielectric layer 106 may provide reduced gate oxide defects and enhanced electrical field strength which result in low gate leakage current, high drive current, and a relatively stable threshold voltage when compared to an a-Si TFT. In addition, channel 112 is formed with sputter zinc indium oxide (ZIO) in one embodiment. The use of ZIO in channel 112 provides a high quality interface between gate dielectric layer 106 and channel 112 that allows for improved performance and stability.

In addition to the ALD process for gate dielectric layer 106, TFT 100 is formed using conventional semiconductor deposition, photo patterning, and etch processes at room temperature in one embodiment. As a result, the room temperature processes along with the low temperature annealing allow TFT 100 to be formed on a low temperature substrate 102, such as plastic.

Substrate 102 may be formed of any suitable flexible or rigid material such as free standing plastic (e.g., polyethylene naphthalate (PEN)) or glass. In one embodiment, substrate 102 may be a low temperature substrate (i.e., has a temperature limitation of 200° C.) that may limit the maximum temperature of the process used to form TFT 100. Substrate 102 may melt or otherwise deform if exposed to a temperature above the maximum temperature of the process used to form TFT 100 in this embodiment. In other embodiments, substrate 102 may be formed of a material that is capable of withstanding substantially higher temperatures than those used in the manufacturing process of TFT 100. In one embodiment, substrate 102 is approximately 125 μm thick as measured in the y-direction shown in FIG. 1. In other embodiments, substrate 102 has other suitable thicknesses.

Gate electrode 104 is formed from an electrically conductive material, such a conductive film stack made of chromium/gold (Cr/Au) or chromium/aluminum (Cr/Al), that is sputtered onto substrate 102 in one embodiment. In other embodiments, the electrically conductive material that forms gate electrode 104 may be applied onto substrate 102 using other chemical or physical vapor deposition techniques, for example. Once applied onto substrate 102, the electrically conductive material may be photo patterned with a wet etch only process to form gate electrode 104 in one embodiment. In other embodiments, other patterning processes may be used to form gate electrode 104. In one embodiment, gate electrode 104 has a width of approximately 100 nm in the x-direction shown in FIG. 1 and a depth of approximately 10 nm in the y-direction shown in FIG. 1. In other embodiments, gate electrode 104 has another suitable width and/or depth.

Gate dielectric layer 106 is a thin film material with a high dielectric constant (κ) and is applied onto substrate 102 and gate electrode 104 using a low temperature (e.g., less than 200° C.) atomic layer deposition (ALD) process. The ALD process results in a low defect, high quality gate dielectric layer 106. Gate dielectric layer 106 forms an insulation layer between gate electrode 104 and source and drain electrodes 108 and 110. In one embodiment, the high κ material is one of hafnium oxide (HfO₂), with a dielectric constant of approximately 30, and zirconium oxide (ZrO₂), with a dielectric constant of approximately 25. In other embodiments, the high κ material may be other materials. In one embodiment, gate dielectric layer 106 has a depth of approximately 50 nm in the y-direction shown in FIG. 1. In other embodiments, gate dielectric layer 106 has another suitable depth.

As used herein the term high κ material refers to a material with a relatively high dielectric constant (e.g., a dielectric constant in the range of 18 to 30) as compared to silicon dioxide which has a dielectric constant of approximately 3.9 at 300K. The high quality low temperature ALD high κ material of gate dielectric layer 106 may provide a higher field strength to minimize field-induced turn on voltage shift, fewer bulk defects to minimize bulk contribution, and a more stable film than a lower κ material.

Source electrode 108 and drain electrode 110 are each formed from an electrically conductive material, such as indium tin oxide (ITO), that is sputtered onto gate dielectric layer 106 in one embodiment. In other embodiments, the electrically conductive material that forms source electrode 108 and drain electrode 110 may be applied onto gate dielectric layer 106 using other chemical or physical vapor deposition techniques, for example. Once applied onto gate dielectric layer 106, the electrically conductive material may be photo patterned with a wet etch only process to form source electrode 108 and drain electrode 110 in one embodiment. In other embodiments, other patterning processes may be used to form source electrode 108 and drain electrode 110.

Channel 112 is formed from a thin film metal oxide semiconductor material, such as zinc indium oxide (ZIO), that is sputtered onto gate dielectric layer 106, source electrode 108, and drain electrode 110 at room temperature and patterned in one embodiment. In other embodiments, the thin film metal oxide semiconductor material that forms channel 112 may be applied onto gate dielectric layer 106, source electrode 108, and drain electrode 110 using other chemical or physical vapor deposition techniques, for example. Once applied, the layer of semiconductor material may be photo patterned with a wet etch only process to form channel 112 between and overlapping with source electrode 108 and drain electrode 110 in one embodiment. In other embodiments, other patterning processes may be used to form channel 112 between and overlapping with source electrode 108 and drain electrode 110 such as another conventional semiconductor patterning technique or a lift-off technique.

Passivation layer 114 is an organic or inorganic thin film photoresist material that is applied onto gate dielectric layer 106, source electrode 108, drain electrode 110, and channel 112 using any suitable technique. Once applied, passivation layer 114 may be photo patterned with a wet etch only process to cover channel 112 in one embodiment. In other embodiments, other patterning processes may be used to pattern passivation layer 114.

The above configuration of TFT 100 shown FIG. 1 is shown by way of example. Other embodiments may include other configurations of the structures shown in FIG. 1.

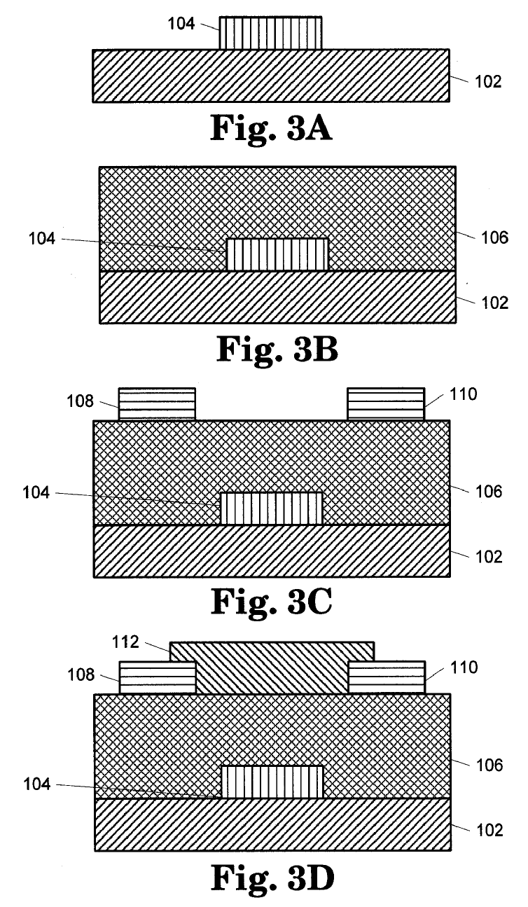

FIG. 2 is a flow chart illustrating an embodiment of a method for forming low temperature TFT 100. The method is illustrated with reference to the cross sectional views of TFT 100 shown in FIGS. 3A-3D at various points in the formation process.

Gate electrode 104 is formed on substrate 102 as indicated in a block 202. In one embodiment, a layer of conductive film stack made of chromium/gold (Cr/Au) or chromium/aluminum (Cr/Al) is sputtered onto substrate 102 at room temperature. Gate electrode 104 is then formed from the layer of conductive film stack using a photo patterning and wet etch only process at room temperature. In other embodiments, gate electrode 104 may be made using other any other suitable processes for a low temperature substrate 102. FIG. 3A shows gate electrode 104 formed on substrate 102.

Gate dielectric layer 106 is formed on substrate 102 and gate electrode 104 with a high κ dielectric material using ALD at a low temperature (e.g., less than 200° C.) as indicated in a block 204. The ALD process produces a low defect, high quality gate dielectric layer 106. With ALD, a hydroxyl (OH) bond is flashed onto the surface substrate 102 by applying water vapor (H₂O) to substrate 102. A precursor material is then applied to react with the absorbed hydroxyl surface groups until the hydroxyl surface is passivated. In one embodiment, the precursor is tetrakis(dimethylamido)hafnium(IV) [(CH₃)₂N]₄Hf which combines with the hydroxyl surface groups to form a layer of hafnium oxide (HfO₂) on substrate 102. In another embodiment, the precursor is tetrakis(dimethylamido) zirconium(IV) [(CH₃)₂N]₄Zr which combines with the hydroxyl surface groups to form a layer of zirconium oxide (ZrO₂) on substrate 102. In both embodiments, the excess precursor material and the byproducts of the reaction are pumped away. The process steps of applying water vapor, applying the precursor, and removing the excess precursor material and byproducts are repeated until the desired number of layers of high κ dielectric material are formed. In one embodiment, the ALD process continues adding layers until gate dielectric layer 106 has a depth of approximately 50 nm in the y-direction shown in FIG. 1. In other embodiments, gate dielectric layer 106 may be formed to have other depths, such as depths in the range of 30 to 100 nm, using the ALD process. FIG. 3B shows gate dielectric layer 106 formed on gate substrate 102 and electrode 104.

Source and drain electrodes 108 and 110 are formed on gate dielectric layer 106 as indicated in a block 206. In one embodiment, a layer of indium tin oxide (ITO) is sputtered onto gate dielectric layer 106 at room temperature. Source and drain electrodes 108 and 110 are then formed from the layer of indium tin oxide using a photo patterning and wet etch only process at room temperature. In other embodiments, source and drain electrodes 108 and 110 may be made using other any other suitable processes for a low temperature substrate 102. FIG. 3C shows source and drain electrodes 108 and 110 formed on gate dielectric layer 106.

A zinc indium oxide (ZIO) channel 112 is formed on gate dielectric layer 106 between and overlapping with source and drain electrodes 108 and 110 as indicated in a block 208. In one embodiment, a layer of ZIO is sputtered onto gate dielectric layer 106 and source and drain electrodes 108 and 110 at room temperature. Channel 112 is then formed from the layer of ZIO using a photo patterning and wet etch only process at room temperature. In other embodiments, channel 112 may be made using any other suitable processes for a low temperature substrate 102 such as another conventional semiconductor patterning technique or a lift-off technique. FIG. 3D shows channel 112 formed on gate dielectric layer 106 and between source and drain electrodes 108 and 110. In one embodiment, channel 112 has a depth of approximately 50 nm in the y-direction shown in FIG. 1. In other embodiments, channel 112 may be formed to have other depths, such as depths in the range of 20 to 50 nm.

Passivation layer 114 is formed on channel 112 as indicated in a block 210. In one embodiment, a layer of an organic or inorganic thin film photoresist is applied onto gate dielectric layer 106, source and drain electrodes 108 and 110, and channel 112 at room temperature. Passivation layer 114 is then formed from the layer of photoresist using a photo patterning and wet etch only process at room temperature. In other embodiments, passivation layer 114 may be made using other any other suitable processes for a low temperature substrate 102. FIG. 1 shows passivation layer 114 formed on channel 112.

TFT 100 is developed at a low temperature as indicated in a block 212. In one embodiment, TFT 100 is developed at a temperature of 175° C. for 1 hr in air. In other embodiments, other development temperatures, such as those between 150° C. and 200° C. may be used that allow TFT 100 to be manufactured on a low temperature substrate 102.

The embodiments described above may provide advantages over TFTs with other low temperature gate dielectric layers, such as aluminum oxide based and organic dielectric layers. A TFT with an aluminum oxide gate dielectric layer may exhibit large threshold voltage shifts during sequential electrical scans or under stress conditions. Such devices may also have a large hysterisis under different voltage polarity, threshold voltages that depend on voltage ranges, and large variations in threshold voltage.

The embodiments described above may advantageously produce a low gate leakage current (e.g., below 1E-10 A), a high on/off current ratio (Iₒₙ/I_{off}) (e.g., approximately 1E6), better gate controllability (e.g., a sub threshold slope, S, of approximately 200 mV/decade compared to approximately 300 mV/decade for Al₂O₃), and good drive current capability (e.g., I_{ds}/(W/L) of approximately 15 μA/μm/μm compared to approximately 2 pA/μm/μm for low temperature ALD Al₂O₃).

In addition, the embodiments described above may exhibit little or no threshold voltage shift during sequential electrical scan (e.g., approximately 0-200 mV compared to approximately 300-2000 mV for Al₂O₃) and have a reduced threshold voltage shift under stress (e.g., approximately 0.5 V compared to approximately 4 V for Al₂O₃). Further, the embodiments described above may provide a much reduced hysterisis under different voltage polarity and a threshold voltage that is independent of the voltage range.

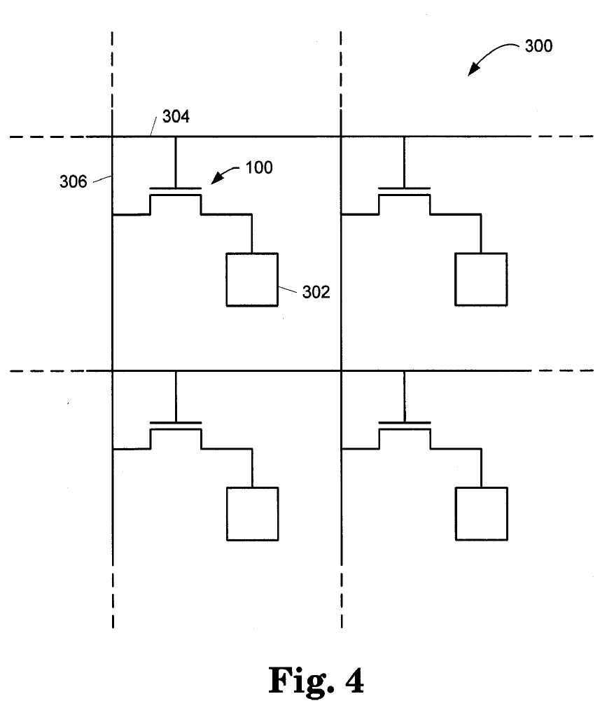

Embodiments of the TFT described above may be included in any suitable flexible or rigid electronic circuitry. For example, an array of the TFTs may be used to control the operation of pixels in electronic paper (e-paper) or flexible or rigid display devices. FIG. 4 is schematic diagram illustrating an embodiment of a display array that includes the low temperature thin film transistor of FIG. 1.

In the embodiment of FIG. 4, a TFT 100 controls the operation of each pixel element 302 (e.g., a liquid crystal element). Each pixel element is controlled (i.e., turned on and turned off) by voltage signals provided on a respective row conductor 304 connected to gate electrode 102 of TFT 100 and a respective column conductor 306 connected to source electrode 108 of TFT 100. Each TFT 100 turns on in response to receiving a voltage signal on a respective row conductor 304 and conducts current across channel 112 in response to receiving a voltage difference between a respective column conductor 306 and a respective pixel element 302.

Although specific embodiments have been illustrated and described herein for purposes of description of the embodiments, it will be appreciated by those of ordinary skill in the art that a wide variety of alternate and/or equivalent implementations may be substituted for the specific embodiments shown and described without departing from the scope of the present disclosure. Those with skill in the art will readily appreciate that the present disclosure may be implemented in a very wide variety of embodiments. This application is intended to cover any adaptations or variations of the disclosed embodiments discussed herein. Therefore, it is manifestly intended that the scope of the present disclosure be limited by the claims and the equivalents thereof.

What is claimed is:

1. A thin film transistor (TFT) comprising:
a substrate;
a gate electrode on the substrate;
an atomic layer deposition film with a high dielectric constant on the gate electrode and the substrate;
a source connection on the film;
a drain connection on the film; and
a zinc indium oxide (ZIO) channel on the film between the source and drain connections.

2. The TFT of claim 1 wherein the high dielectric constant atomic layer deposition film is one of hafnium oxide (HfO₂) and zirconium oxide (ZrO₂).

3. The TFT of claim 1 wherein the high dielectric constant is greater than or equal to 18.

4. The TFT of claim 1 wherein the gate electrode is formed from a conductive film stack made from one of chromium/gold and chromium/aluminum.

5. The TFT of claim 1 wherein the source and the drain electrodes are formed from indium tin oxide.

6. The TFT of claim 1 further comprising:
a passivation layer on the ZIO channel.

7. A method for fabricating a thin film transistor (TFT), the method comprising:
forming a gate electrode on a substrate;
forming an atomic layer deposition gate dielectric layer with high dielectric constant on the gate electrode and the substrate;
forming source and drain electrode on the gate dielectric layer; and
forming a zinc indium oxide channel on the gate dielectric layer between the source and drain connections.

8. The method of claim 7 further comprising:
forming the gate dielectric layer by applying water vapor, applying a precursor material, and removing excess precursor material and byproducts.

9. The method of claim 8 wherein the precursor material is one of tetrakis(dimethylamido) hafnium(IV) ([(CH₃)₂N]₄Hf) and tetrakis(dimethylamido)zirconium(IV) ([(CH₃)₂N]₄Zr).

10. The method of claim 7 wherein the gate dielectric layer is one of hafnium oxide (HfO₂) and zirconium oxide (ZrO₂).

11. The method of claim 7 further comprising:
annealing the TFT at a temperature between 150° C. and 200° C.

12. The method of claim 7 further comprising:
forming a passivation layer on the zinc indium oxide channel.

13. The method of claim 7 further comprising:
forming the zinc indium oxide channel by sputtering zinc indium oxide.

14. The method of claim 7 further comprising:
forming the gate electrode by sputtering an electrically conductive material.

15. The method of claim 7 further comprising:
forming the source and the drain electrodes by sputtering an electrically conductive material

16. The method of claim 7 wherein the substrate is a low temperature substrate.

17. A method comprising:
providing a substrate;
providing a gate electrode on the substrate;
providing an atomic layer deposition gate dielectric layer with high dielectric constant on the gate electrode and the substrate;
providing a source connection on the gate dielectric layer;
providing a drain connection on the gate dielectric layer; and
providing a zinc indium oxide (ZIO) channel on the gate dielectric layer between the source and drain connections.

18. The method of claim 18 wherein the gate dielectric layer is one of hafnium oxide (HfO₂) and zirconium oxide (ZrO₂).

19. The method of claim 18 wherein the substrate is a low temperature substrate.

20. The method of claim 18 further comprising:
providing a passivation layer on the ZIO channel.
